(19) United States
(12) Patent Application Publication
(10) Pub. No.: US 2025/0234579 A1
(43) Pub. Date: Jul. 17, 2025

(54) NITRIDE SEMICONDUCTOR DEVICE

(71) Applicant: ROHM CO., LTD., Kyoto-shi (JP)

(72) Inventor: Keita SHIKATA, Kyoto-shi (JP)

(73) Assignee: ROHM CO., LTD., Kyoto-shi (JP)

(21) Appl. No.: 19/097,870

(22) Filed: Apr. 2, 2025

Related U.S. Application Data
(63) Continuation of application No. PCT/JP2023/028989, filed on Aug. 8, 2023.

(30) Foreign Application Priority Data
Oct. 6, 2022 (JP) 2022-161446

(51) Int. Cl. H10D 30/47; H10D 30/01; H10D 62/40; H10D 62/60; H10D 62/824; H10D 62/832; H10D 86/00

(52) U.S. Cl. CPC H10D 30/475; H10D 62/405; H10D 62/605; H10D 62/824; H10D 62/8325; H10D 86/201; H10D 30/015

(57) ABSTRACT

A nitride semiconductor device includes a SiC substrate having a hexagonal crystal structure and including a main surface inclined with respect to a c-plane at an off-angle from 2° to 6° in a specific crystal direction, a nitride semiconductor layer located on the main surface of the SiC substrate and including an electron transit layer and an electron supply layer, and a gate electrode, a source electrode, and a drain electrode located on the nitride semiconductor layer. The main surface is parallel to a first direction, a second direction orthogonal to the first direction, and a third direction coinciding with the specific crystal direction in plan view. The source electrode and the drain electrode are separated in the first direction. The gate electrode extends in the second direction between the source electrode and the drain electrode. The first direction intersects the third direction at an angle of 90°±15°.

### CROSS-REFERENCE TO RELATED APPLICATIONS

This application is a continuation of and claims the benefit of priority from International Application No. PCT/JP2023/028989, filed on Aug. 8, 2023, which claims the benefit of priority from Japanese Patent Application No. 2022-161446, filed on Oct. 6, 2022, the entire contents of each of which are incorporated herein by reference.

### BACKGROUND

### 1. Field

The present disclosure relates to a nitride semiconductor device.

### 2. Description of Related Art

High electron mobility transistors (HEMTs) are widely used as high-speed switching devices and high-frequency amplifying devices. In particular, when a nitride semiconductor having a relatively large band gap is used in a HEMT, the HEMT performs a high-speed operation with a high breakdown voltage. Japanese Laid-Open Patent Publication No. 2020-077865 discloses an example of a semiconductor device that includes a semiconductor substrate, a buffer layer located on the semiconductor substrate, an electron transit layer located on the buffer layer, and an electron supply layer located on the electron transit layer. The electron transit layer and the electron supply layer are formed from nitride semiconductors having different band gaps (different Al compositions). When the electron transit layer and the electron supply layer form a heterojunction, a two-dimensional electron gas (2DEG) is generated in the electron transit layer in the proximity of the interface between the electron transit layer and the electron supply layer. The 2DEG may be used as a channel of the HEMT.

### BRIEF DESCRIPTION OF THE DRAWINGS

FIG. 1 is a schematic plan view of an exemplary nitride semiconductor device in accordance with one embodiment.

FIG. 2 is a schematic cross-sectional view of the nitride semiconductor device taken along line F2-F2 shown in FIG. 1.

FIG. 3 is a schematic diagram showing a crystal structure of a SiC substrate having an off-angle.

FIG. 4 is a schematic cross-sectional view showing a step of manufacturing a nitride semiconductor device.

FIG. 5 is a schematic cross-sectional view showing a manufacturing step subsequent to the step shown in FIG. 4.

FIG. 6 is a schematic cross-sectional view showing a manufacturing step subsequent to the step shown in FIG. 5.

FIG. 7 is a schematic cross-sectional view showing a manufacturing step subsequent to the step shown in FIG. 6.

FIG. 8 is a schematic cross-sectional view showing a manufacturing step subsequent to the step shown in FIG. 7.

FIG. 9 is a schematic cross-sectional view showing a manufacturing step subsequent to the step shown in FIG. 8.

FIG. 10 is a schematic cross-sectional view of an exemplary nitride semiconductor device in accordance with a comparative example.

### DETAILED DESCRIPTION

Embodiments of a nitride semiconductor device in accordance with the present disclosure will now be described with reference to the accompanying drawings. Throughout the drawings and the detailed description, the same reference numerals refer to the same elements. The drawings may not be to scale, and the relative size, proportions, and depiction of elements in the drawings may be exaggerated for clarity, illustration, and convenience.

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

### Planar Layout of Nitride Semiconductor Device

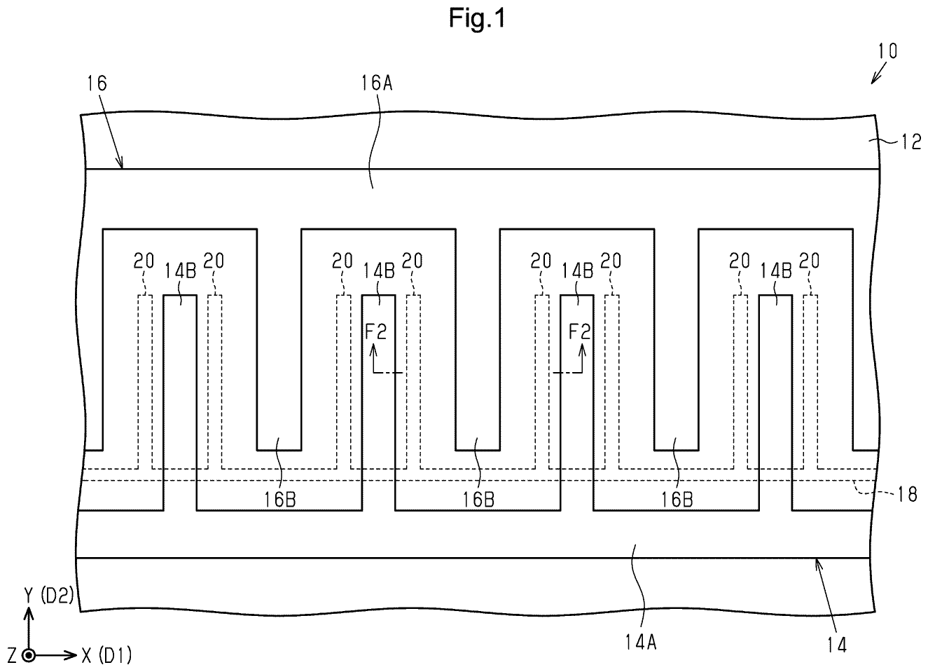

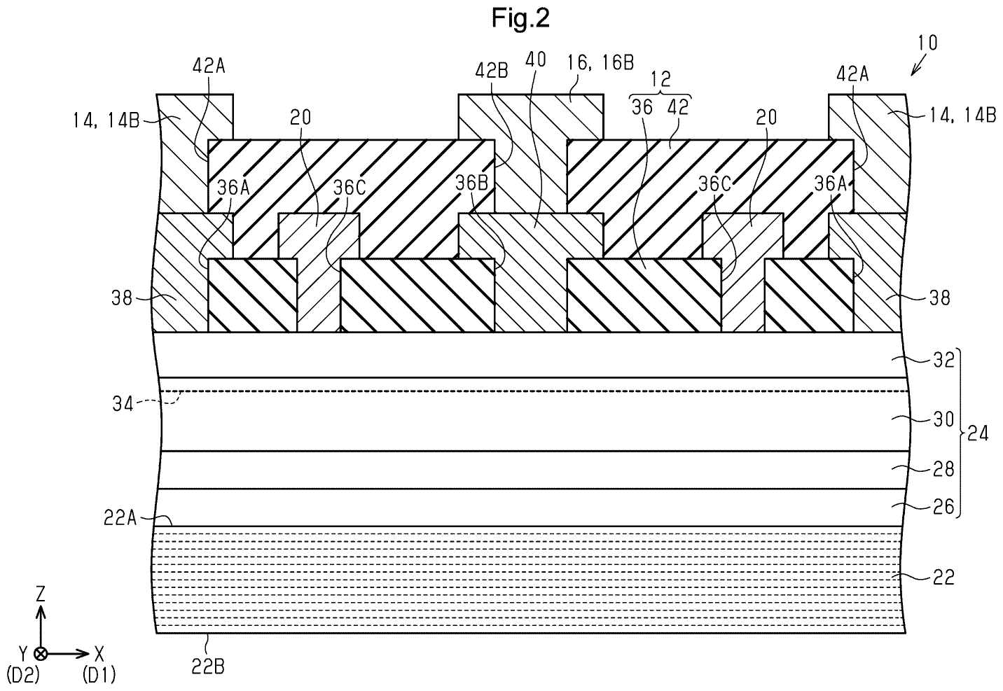

FIG. 1 is a schematic plan view of an exemplary nitride semiconductor device 10 in accordance with one embodiment. The nitride semiconductor device 10 may include an insulation layer 12, a source interconnect 14, and a drain interconnect 16. The source interconnect 14 and the drain interconnect 16 may be located on the insulation layer 12. FIG. 1 shows X, Y, and Z axes that are orthogonal to one another. The Z-axis direction is orthogonal to a main surface 22A (refer to FIG. 2) of a SiC substrate 22, which will be described later. Unless otherwise indicated, the term “plan view” as used in this specification will refer to a view of the nitride semiconductor device 10 taken from above in the Z-axis direction.

The insulation layer 12 may be formed from any insulation material that insulates the source interconnect 14 and the drain interconnect 16. For example, the insulation layer 12 may include SiO₂, SiN, SION, Al₂O₃, AlN, AlON, HfO, HfN, HfON, HfSiON, AlON, or any combination thereof.

The source interconnect 14 and the drain interconnect 16 may be formed from one or more conductive materials. In an example, the source interconnect 14 and the drain interconnect 16 may each include Au, Ti, TiN, Pt, Cu, Al, AlSiCu, AlCu, or any combination thereof.

As shown in FIG. 1, the source interconnect 14 may include a base 14A and source fingers 14B connected to the base 14A. In the illustrated example, the base 14A extends in the X-axis direction, and the source fingers 14B extend in the Y-axis direction. In the same manner, the drain interconnect 16 may include a base 16A and drain fingers 16B connected to the base 16A. In the illustrated example, the base 16A extends in the X-axis direction, and the drain fingers 16B extend in the Y-axis direction. In the present disclosure, the X-axis direction and the Y-axis direction may be referred to as “the first direction” and “the second direction”, respectively. The source fingers 14B and the drain fingers 16B may be separated from each other and arranged alternately. In the illustrated example, the source fingers 14B and the drain fingers 16B are alternately arranged in the X-axis direction.

The nitride semiconductor device 10 may further include a gate interconnect 18 and gate electrodes 20 connected to the gate interconnect 18. The gate interconnect 18 and the gate electrodes 20 may be located below the source interconnect 14 and the drain interconnect 16 and covered by the insulation layer 12. In the illustrated example, the gate interconnect 18 extends in the X-axis direction, and the gate electrodes 20 extend in the Y-axis direction. In plan view, each gate electrode 20 may be located between one of the source fingers 14B and one of the drain fingers 16B. In the illustrated example, in plan view, each gate electrode 20 is located between one of the source fingers 14B and one of the drain fingers 16B that are opposed to each other in the X-axis direction. In plan view, the gate interconnect 18 may extend between the base 14A of the source interconnect 14 and the drain fingers 16B. Alternatively, in plan view, the gate interconnect 18 may extend between the base 16A of the drain interconnect 16 and the source fingers 14B. The gate electrode 20 will be described later further in detail with reference to FIG. 2.

### Cross-Sectional Structure of Nitride Semiconductor Device

FIG. 2 is a schematic cross-sectional view of the nitride semiconductor device 10 taken along line F2-F2 shown in FIG. 1. The nitride semiconductor device 10 includes a SiC substrate 22 having a hexagonal crystal structure and having a main surface 22A and a nitride semiconductor layer 24 located on the main surface 22A of the SiC substrate 22. The SiC substrate 22 also includes a back surface 22B opposite to the main surface 22A. In the present disclosure, the term “main surface” refers to a surface of the SiC substrate 22 on which the nitride semiconductor layer 24 epitaxially grows (surface that is in contact with the nitride semiconductor layer 24, or an epitaxial layer). The main surface 22A is parallel to a first direction D1 (X-axis direction) and a second direction D2 (Y-axis direction). The second direction D2 is orthogonal to the first direction D1 in plan view.

The SiC substrate 22 has an off-angle θ_{off}. The main surface 22A is inclined with respect to the c-plane by the off-angle θ_{off} in a specific crystal direction. The off-angle θ_{off} may be in a range from 2° to 6°, inclusive. Preferably, the off-angle θ_{off} may be in a range from 3° to 5°, inclusive, and further preferably, in a range from 3.5° to 4.5°, inclusive. In the present disclosure, the term “c-plane” refers to the (0001) surface of a SiC hexagonal crystal.

In the present embodiment, the specific crystal direction may be a [11-20] direction. More specifically, the main surface 22A may be inclined with respect to the c-plane by an off-angle θ_{off} in a range from 2° to 6°, inclusive, in the [11-20] direction. In the present disclosure, in an index indicating a crystal direction or a surface, a number provided with a minus sign in front (e.g., “2” in [11-20] direction) indicates that a number with an upper bar.

The SiC substrate 22 may be a 4H—SiC substrate. The term “4H” indicates a polytype of a SiC crystal. The SiC substrate 22 may be electrically conductive. The resistivity of the SiC substrate 22 may be, for example, in a range from 0.01 Ω·cm (ohm centimeter), which is equal to 1 Ω·m (ohm meter), to 0.03 Ω·cm (3 Ω·m), inclusive. In the present embodiment, the resistivity of the SiC substrate 22 may be approximately 0.02 Ω·cm (=2 Ω·m). The SiC substrate 22 may have a thickness in a range from, for example, 30 μm (micrometer) to 300 μm, inclusive. In the present embodiment, the thickness of the SiC substrate 22 may be 150 μm.

The nitride semiconductor layer 24 is an epitaxial layer located on the main surface 22A of the SiC substrate 22. In the present embodiment, the nitride semiconductor layer 24 may include a buffer layer 26 located on the SiC substrate 22 and a semi-insulating layer 28 located on the buffer layer 26.

The buffer layer 26 may be formed from, for example, any material that limits warping of the SiC substrate 22 caused by a mismatch of the coefficients of thermal expansion between the SiC substrate 22 and the semi-insulating layer 28 and formation of cracks in the nitride semiconductor device 10. For example, the buffer layer 26 may include at least one of an aluminum nitride (AlN) layer, an aluminum gallium nitride (AlGaN) layer, and a graded AlGaN layer that has different aluminum (Al) compositions. The buffer layer 26 may be a single AlN layer, a single AlGaN layer, a layer having an AlGaN/GaN superlattice structure, a layer having an AlN/AlGaN superlattice structure, or a layer having an AlN/GaN superlattice structure. In the present embodiment, the buffer layer 26 may include a first buffer layer that is an AlN layer located on the main surface 22A of the SiC substrate 22 and a second buffer layer that is an AlGaN layer located on the AlN layer. The buffer layer 26 may have a thickness in a range from 5 nm to 2 μm, inclusive. In the present embodiment, the thickness of the buffer layer 26 may be approximately 0.8 μm.

The semi-insulating layer 28 may be a GaN layer doped with an impurity. The semi-insulating layer 28 may be arranged to reduce leakage current. The impurity may be, for example, carbon (C) or iron (Fe). Alternatively, the impurity may include both C and Fe. The GaN layer may be doped with the impurity so that the difference (Na—Nd) between acceptor concentration Na and donor concentration Nd is approximately 1×10¹⁷ cm⁻³. The semi-insulating layer 28 may have a thickness in a range from 1 μm to 10 μm, inclusive. In the present embodiment, the thickness of the semi-insulating layer 28 may be 2 μm.

The nitride semiconductor layer 24 further includes an electron transit layer 30 and an electron supply layer 32 located on the electron transit layer 30. The electron transit layer 30 may be located on the semi-insulating layer 28. The electron transit layer 30 may be composed of GaN. In the present embodiment, the electron transit layer 30 may be an n-type GaN layer doped with a donor impurity. In another example, the electron transit layer 30 may be an undoped GaN layer. The electron transit layer 30 may have a thickness in a range from 0.05 μm to 1 μm, inclusive. In the present embodiment, the thickness of the electron transit layer 30 may be approximately 0.2 μm.

The electron supply layer 32 has a larger band gap than the electron transit layer 30. In the present embodiment, the electron supply layer 32 may be composed of AlₓGa₁₋ₓN, where 0<x≤1. Preferably, 0.1<x<0.3. As the Al composition increases, the band gap of AlGaN becomes larger. In the present embodiment, X may be equal to 0.2. The electron supply layer 32 may have a thickness in a range from 1 nm to 100 nm, inclusive. In the present embodiment, the thickness of the electron supply layer 32 may be approximately 20 nm.

The electron transit layer 30 and the electron supply layer 32 are each composed of a nitride semiconductor having a different lattice constant. Thus, a heterojunction with lattice mismatch is formed between a nitride semiconductor forming the electron transit layer 30 (e.g., GaN) and a nitride semiconductor forming the electron supply layer 32 (e.g., AlGaN). The spontaneous polarization of the electron transit layer 30 and the electron supply layer 32 and the piezoelectric polarization caused by crystal strain in the proximity of the heterojunction interface result in the energy level of the conduction band of the electron transit layer 30 being lower than the Fermi level in the proximity of the heterojunction interface. As a result, two-dimensional electron gas 34 (2DEG) is generated in the electron transit layer 30 at a location close to the heterojunction interface between the electron transit layer 30 and the electron supply layer 32 (e.g., within a range approximately a few nanometers from the interface). The 2DEG 34 in the electron transit layer 30 is used as a channel of the nitride semiconductor device 10. The sheet carrier density of the 2DEG 34, which is generated in the electron transit layer 30, will be increased when at least one of the Al composition and the thickness of the electron supply layer 32 is increased.

The nitride semiconductor device 10 may further include a first insulation layer 36 located on the electron supply layer 32. The first insulation layer 36 includes a source contact opening 36A, a drain contact opening 36B, and a gate contact opening 36C that expose the surface of the electron supply layer 32. The source contact opening 36A and the drain contact opening 36B are separated from each other in the X-axis direction. The gate contact opening 36C is located between the drain contact opening 36B and the source contact opening 36A, which are separated in the X-axis direction. The first insulation layer 36 may include SiO₂, SiN, SiON, Al₂O₃, AlN, AlON, HfO, HfN, HfON, HfSiON, AlON or any combination thereof. In the present embodiment, the first insulation layer 36 may be SiN. The first insulation layer 36 may have a thickness, for example, in a range from 10 nm to 200 nm, inclusive. In the present embodiment, the thickness of the first insulation layer 36 may be approximately 100 nm. The first insulation layer 36 is a portion of the insulation layer 12.

The nitride semiconductor device 10 includes the gate electrode 20, a source electrode 38, and a drain electrode 40 that are located on the nitride semiconductor layer 24. The source electrode 38 and the drain electrode 40 are separated from each other in the first direction D1 (X-axis direction). The gate electrode 20 is located between the drain electrode 40 and the source electrode 38, which are separated in the first direction D1. The source electrode 38, the drain electrode 40, and the gate electrode 20 are arranged to allow electrons to be transmitted through the 2DEG 34 in the first direction D1. The source electrode 38 is in contact with the electron supply layer 32 through the source contact opening 36A. The drain electrode 40 is in contact with the electron supply layer 32 through the drain contact opening 36B. The gate electrode 20 is in contact with the electron supply layer 32 through the gate contact opening 36C.

The source electrode 38 and the drain electrode 40 may be formed from any material capable of forming an ohmic contact with the nitride semiconductor layer 24. In the present embodiment, the source electrode 38 and the drain electrode 40 may include a Ti layer and an Al layer. In this case, the Ti layer may be located between the first insulation layer 36 and the Al layer. In an example, the Ti layer may have a thickness of approximately 20 nm, and the Al layer may have a thickness of approximately 300 nm. In another example, the source electrode 38 and the drain electrode 40 may include a Ta layer and an Al layer. In another example, the source electrode 38 and the drain electrode 40 may include a Ti layer, an Al layer, a Ni layer, and a Au layer in this order from below.

The gate electrode 20 may be formed from any material capable of forming a Schottky junction with the nitride semiconductor layer 24. In the present embodiment, the gate electrode 20 may include a Ni layer and a Au layer. In this case, the Ni layer may be located between the first insulation layer 36 and the Au layer. In an example, the Ni layer may have a thickness of 10 nm, and the Au layer may have a thickness of 600 nm.

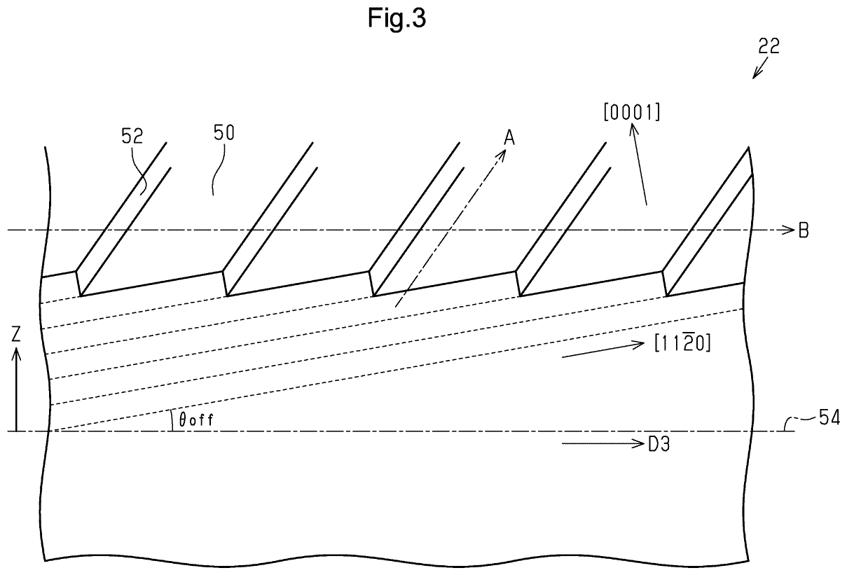

The gate electrode 20 is located between the source electrode 38 and the drain electrode 40, which are separated in the first direction D1 (X-axis direction), and extends in the second direction D2 (Y-axis direction) (refer to FIG. 1). The source electrode 38 and the drain electrode 40 also extend in the second direction D2. More specifically, the source electrode 38, the gate electrode 20, and the drain electrode 40, which extend in the second direction D2, are arranged in this order in the first direction D1. Thus, electrons travel in the first direction D1 between the source electrode 38 and the drain electrode 40 through the 2DEG 34 in the electron transit layer 30. The source electrode 38, the gate electrode 20, and the drain electrode 40 are arranged so that the first direction D1 (i.e., electron traveling direction) satisfies a predetermined relationship with the specific crystal direction ([11-20]) of the SiC substrate 22. The predetermined relationship will be described later with reference to FIG. 3.

The nitride semiconductor device 10 may further include a second insulation layer 42 located on the first insulation layer 36. The second insulation layer 42 includes a first opening 42A exposing a surface of the source electrode 38 and a second opening 42B exposing a surface of the drain electrode 40. The second insulation layer 42 may include SiO₂, SiN, SiON, Al₂O₃, AlN, AlON, HfO, HfN, HfON, HfSiON, AlON, or any combination thereof. In the present embodiment, the second insulation layer 42 may be SiO₂. The second insulation layer 42 may have a thickness of approximately 500 nm. The second insulation layer 42 is a portion of the insulation layer 12. The insulation layer 12 includes the first insulation layer 36 and the second insulation layer 42.

The source interconnect 14 and the drain interconnect 16 are located on the second insulation layer 42. The source finger 14B of the source interconnect 14 is connected to the source electrode 38 through the first opening 42A. The drain finger 16B of the drain interconnect 16 is connected to the drain electrode 40 through the second opening 42B.

The above-described description with reference to FIG. 2 focus on one source electrode 38, one drain electrode 40, and one gate electrode 20 located between the source electrode 38 and the drain electrode 40. However, the nitride semiconductor device 10 may include multiple gate electrodes 20, multiple source electrodes 38, and multiple drain electrodes 40 located on the nitride semiconductor layer 24. Each of the source electrodes 38 may be connected to one of the source fingers 14B (refer to FIG. 1) through the first opening 42A. In the same manner, each of the drain electrodes 40 may be connected to one of the drain fingers 16B (refer to FIG. 1) through the second opening 42B. The source electrodes 38 and the drain electrodes 40 may be alternately located in the first direction D1 (X-axis direction). Each of the gate electrodes 20 may be located between one of the source electrodes 38 and one of the drain electrodes 40.

### Relationship Between Electron Traveling Direction and Specific Crystal Direction of the SiC Substrate

The relationship of the first direction D1 (electron traveling direction) and the specific crystal direction ([11-20]) of the SiC substrate 22 will now be described with reference to FIG. 3. FIG. 3 is a schematic diagram showing a surface structure of the SiC substrate 22 having an off-angle θ_{off}. To facilitate understanding, FIG. 3 schematically shows, at an atomic level, the surface structure of the SiC substrate 22 having an ideal crystal structure.

As shown in FIG. 3, the surface structure of the SiC substrate 22 may include terraces 50 and steps 52 connecting the terraces 50. Each of the terraces 50 is flat at the atomic level. Each of the terraces 50 has a (0001) plane (i.e., c-plane) that is orthogonal to the direction [0001] of a SiC hexagonal crystal. In the drawings, the broken lines provide an imaginary representation of the (0001) plane. Each step 52 connecting the terraces 50 may have a dimension corresponding to one or more atomic layers. To facilitate understanding, the dimensions of the off-angle θ_{off} and the steps 52 are exaggerated in FIG. 3. At the atomic level, the SiC substrate 22 has a step-terrace structure as shown in FIG. 3. However, in an actual SiC substrate 22, the main surface 22A is substantially flat. For the sake of illustration, FIG. 3 shows an imaginary plane 54 parallel to the main surface 22A.

FIG. 3 shows an example in which the main surface 22A is inclined with respect to the c-plane by an off-angle θ_{off} in the [11-20] direction, that is, the specific crystal direction. A direction that coincides with the specific crystal direction in plan view is referred to as a third direction D3. More specifically, the third direction D3 is obtained by projecting the specific crystal direction (in the illustrated example, [11-20] direction) onto the main surface 22A (or imaginary surface 54 parallel to the main surface 22A). The main surface 22A is parallel to the third direction D3. The third direction D3 may also be referred to as an inclination direction of the SiC substrate 22. Since the third direction D3 is parallel to the main surface 22A, an angle formed by the third direction D3 and the specific crystal direction ([11-20] direction) corresponds to the off-angle θ_{off}.

As described above with reference to FIG. 2, the nitride semiconductor layer 24 is an epitaxial layer located on the main surface 22A of the SiC substrate 22. Thus, the nitride semiconductor layer 24 may take on the crystal structure of the main surface 22A of the SiC substrate 22. The structure in which the terraces 50 and the steps 52 continuously alternate in the SiC substrate 22 having the off-angle θ_{off} may affect the electron mobility of the 2DEG 34 generated in the electron transit layer 30 included in the nitride semiconductor layer 24.

In the present embodiment, the source electrode 38, the gate electrode 20, and the drain electrode 40 (refer to FIG. 2) are located so that the first direction D1 satisfies a predetermined relationship with the specific crystal direction of the SiC substrate 22. In the present embodiment, the first direction D1 intersects the third direction D3, which coincides with the specific crystal direction in plan view, at an angle in a range of 90°±15°. As described above, the first direction D1 corresponds to the electron traveling direction. As shown in FIG. 3, the third direction D3 corresponds to a direction intersecting the steps 52 in plan view (refer to arrow B in FIG. 3). In an example, when the first direction D1 intersects the third direction D3 at 90°, the electrons travel in a direction indicated by arrow A in FIG. 3, that is, a direction that does not intersect the steps 52 in plan view. Scattering of electrons when traveling in the direction indicated by arrow A is less than scattering of electrons when traveling in the direction indicated by arrow B. As described above, the first direction D1 intersects the third direction D3 at an angle in a range of 90°±15°. This allows electrons to transmit in a direction in which the scattering of electrons is relatively low.

### Method for Manufacturing the Nitride Semiconductor Device

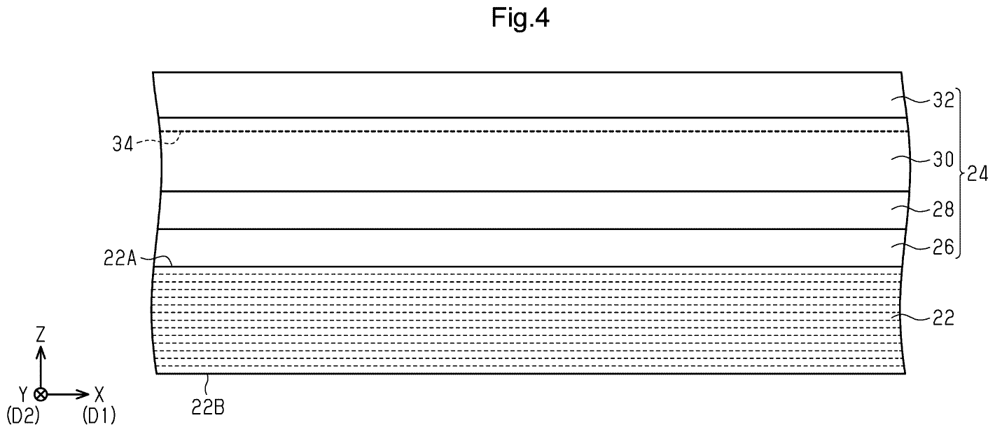

An example of a method for manufacturing the nitride semiconductor device 10 will be described. FIGS. 4 to 9 are schematic cross-sectional views showing exemplary manufacturing steps of the nitride semiconductor device 10. To facilitate understanding, in FIGS. 4 to 9, the same reference characters are given to those components that are the same as the corresponding components shown in FIG. 2.

As shown in FIG. 4, the nitride semiconductor layer 24 is formed on the main surface 22A of the SiC substrate 22. In the present embodiment, the SiC substrate 22 may be a 4H—SiC substrate having a resistivity of approximately 2 Ω·m. The SiC substrate 22 may include a main surface 22A that is inclined with respect to the c-plane by an off-angle θ_{off} of 4° in the [11-20] direction.

Metal organic chemical vapor deposition (MOCVD) processing may be performed so that the nitride semiconductor layer 24 epitaxially grows on the main surface 22A of the SiC substrate 22. The nitride semiconductor layer 24 may include the buffer layer 26 formed on the main surface 22A of the SiC substrate 22 and the semi-insulating layer 28 formed on the buffer layer 26. In the present embodiment, the buffer layer 26 may include a first buffer layer that is an AlN layer formed on the main surface 22A of the SiC substrate 22 and a second buffer layer that is an AlGaN layer formed on the AlN layer. The buffer layer 26 may have a thickness of approximately 0.8 μm. The semi-insulating layer 28 may be a GaN layer doped with C or Fe. In an example, the semi-insulating layer 28 may have a thickness of 2 μm.

The nitride semiconductor layer 24 further includes the electron transit layer 30 and the electron supply layer 32 formed on the electron transit layer 30. The electron transit layer 30 may be formed on the semi-insulating layer 28. In the present embodiment, the electron transit layer 30 may be an n-type GaN layer doped with a donor impurity. The electron transit layer 30 may have a thickness of approximately 0.2 μm. The electron supply layer 32 is composed of AlₓGa₁₋ₓN, where X=0.2. The electron supply layer 32 may have a thickness of approximately 20 nm. When the heterojunction is formed between the electron transit layer 30 and the electron supply layer 32, the two-dimensional electron gas (2DEG) 34 is generated in the electron transit layer 30 at a position proximate to the interface between the electron transit layer 30 and the electron supply layer 32.

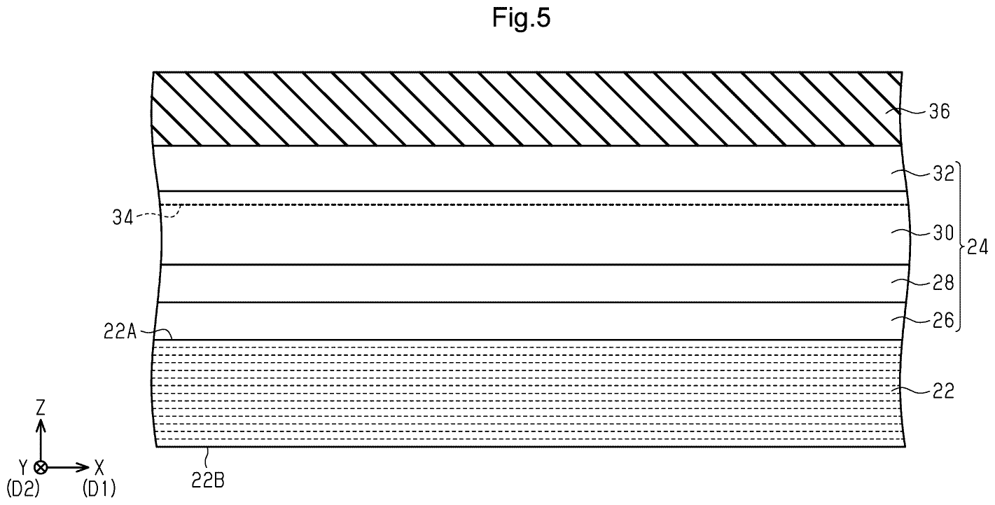

FIG. 5 is a schematic cross-sectional view showing a manufacturing step subsequent to the step shown in FIG. 4. As shown in FIG. 5, a first insulation layer 36 is formed on the nitride semiconductor layer 24. In the present embodiment, the first insulation layer 36 may be a SiN layer having a thickness of approximately 100 nm. In an example, the first insulation layer 36 may be formed through plasma-enhanced chemical vapor deposition (PECVD). In another example, the first insulation layer 36 may be formed through low-pressure chemical vapor deposition (LPCVD), sputtering, atomic layer deposition (ALD), or molecular beam epitaxy (MBE).

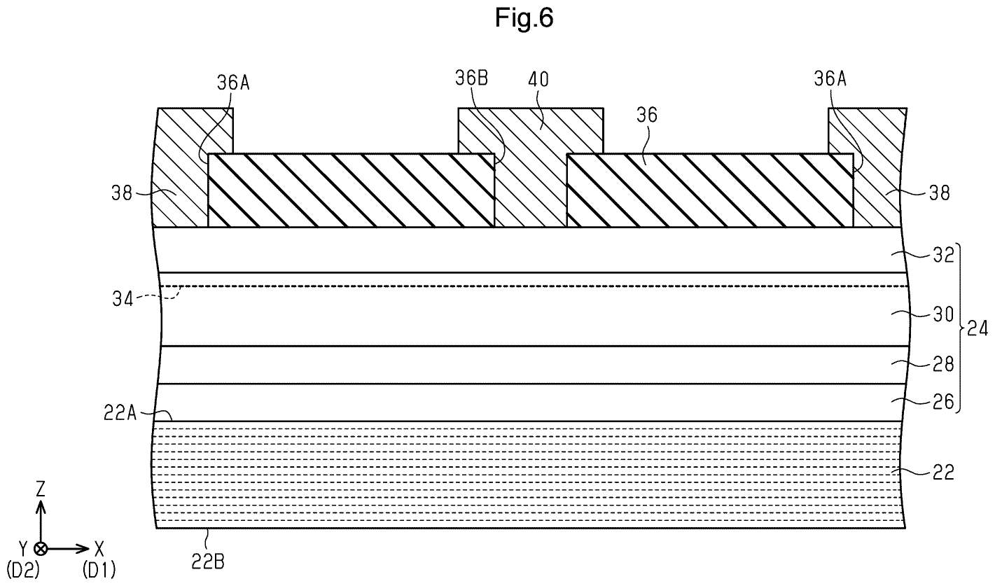

FIG. 6 is a schematic cross-sectional view showing a manufacturing step subsequent to the step shown in FIG. 5. As shown in FIG. 6, the source contact opening 36A and the drain contact opening 36B are formed in the first insulation layer 36. Then, the source electrode 38 and the drain electrode 40 are formed.

In this step, the first insulation layer 36 is selectively removed by etching to form the source contact opening 36A and the drain contact opening 36B that extend through the first insulation layer 36. The source contact opening 36A and the drain contact opening 36B are separated from each other in the first direction D1 (X-axis direction). The first direction D1 intersects the third direction D3, which coincides with the [11-20] direction of the SiC substrate 22 in plan view, at an angle in a range of 90°±15°.

Next, a first metal layer (not shown) is formed on the first insulation layer 36 so as to fill the source contact opening 36A and the drain contact opening 36B. As shown in FIG. 6, the source electrode 38 and the drain electrode 40 are formed of a portion of the first metal layer. In the present embodiment, the first metal layer may include a Ti layer having a thickness of approximately 20 nm and an Al layer formed on the Ti layer and having a thickness of approximately 300 nm. The Ti layer is in contact with the surface of the electron supply layer 32 exposed through the source contact opening 36A and the drain contact opening 36B. Then, annealing at 500° C. to 550° C. is performed to form an ohmic contact between the first metal layer and the nitride semiconductor layer 24. The etching that selectively removes the first metal layer obtains the source electrode 38 and the drain electrode 40 shown in FIG. 6.

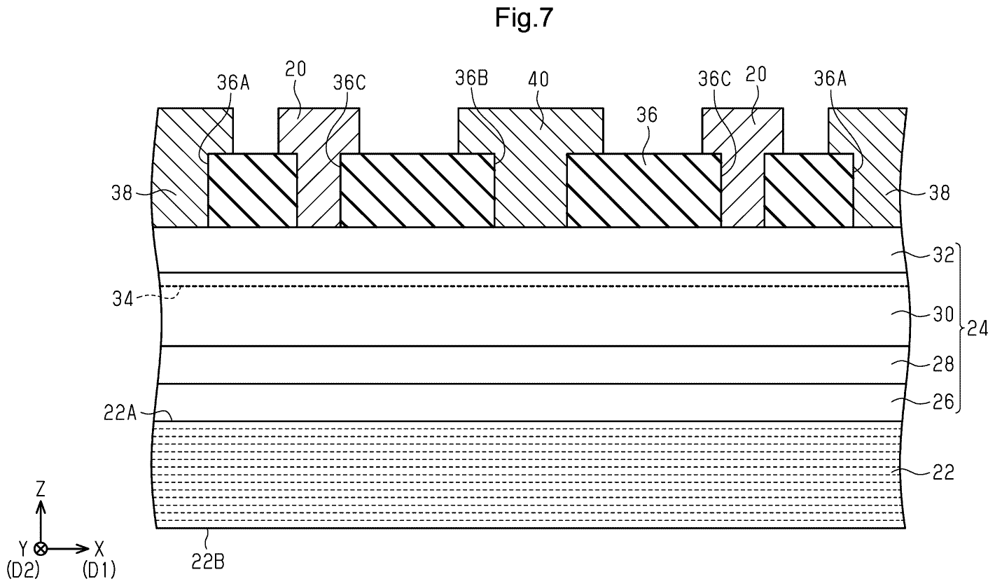

FIG. 7 is a schematic cross-sectional view showing a manufacturing step subsequent to the step shown in FIG. 6. As shown in FIG. 7, the gate contact opening 36C is formed in the first insulation layer 36, and then the gate electrode 20 is formed.

In this step, the first insulation layer 36 is selectively removed by etching to form the gate contact opening 36C extending through the first insulation layer 36. The gate contact opening 36C is located between the drain contact opening 36B and the source contact opening 36A, which are separated in the first direction D1.

Next, a second metal layer (not shown) is formed on the first insulation layer 36 so as to fill the gate contact opening 36C. The gate electrode 20 shown in FIG. 7 is formed of a portion of the second metal layer. In the present embodiment, the second metal layer may include a Ni layer having a thickness of approximately 10 nm and an Au layer formed on the Ni layer and having a thickness of approximately 600 nm. The Ni layer is in contact with the surface of the electron supply layer 32 exposed by the gate contact opening 36C. A Schottky junction is formed between the second metal layer and the nitride semiconductor layer 24. The etching that selectively removes the second metal layer obtains the gate electrode 20 shown in FIG. 7.

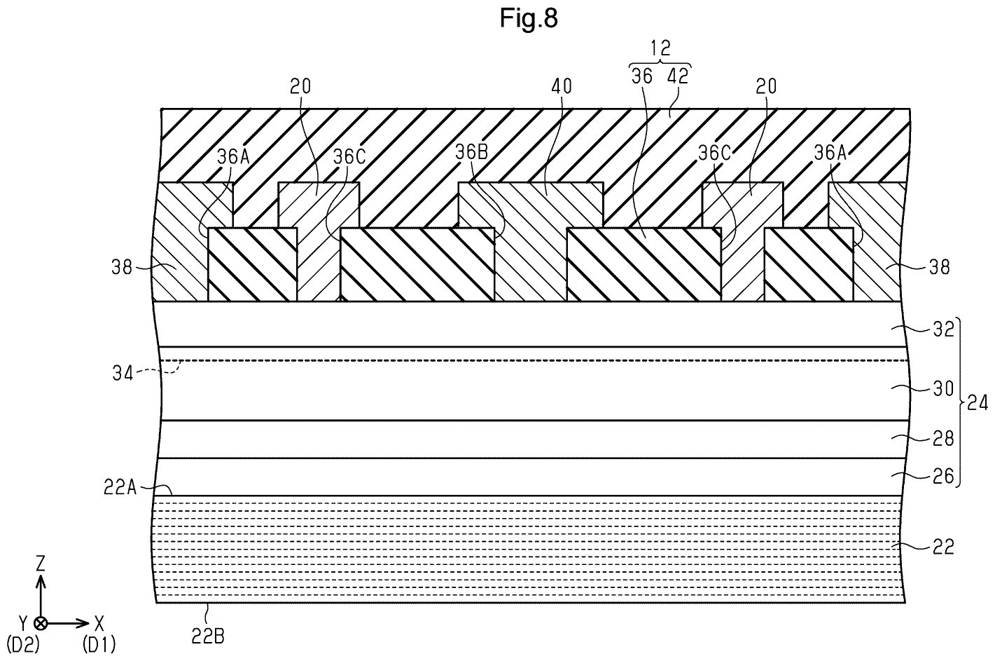

FIG. 8 is a schematic cross-sectional view showing a manufacturing step subsequent to the step shown in FIG. 7. As shown in FIG. 8, the second insulation layer 42 is formed on the first insulation layer 36. The second insulation layer 42 covers the surfaces of the gate electrode 20, the source electrode 38, and the drain electrode 40. In the present embodiment, the second insulation layer 42 may be a SiO₂ layer having a thickness of approximately 500 nm. In an example, the second insulation layer 42 may be formed through PECVD. In another example, the second insulation layer 42 may be formed through LPCVD, sputtering, ALD, or MBE.

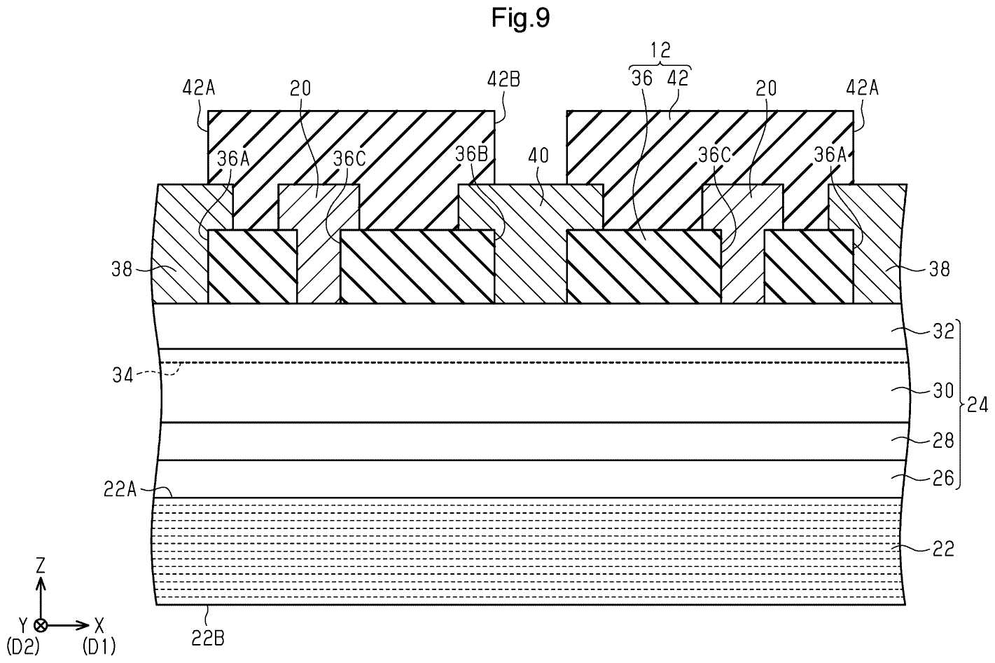

FIG. 9 is a schematic cross-sectional view showing a manufacturing step subsequent to the step shown in FIG. 8. As shown in FIG. 9, the first opening 42A and the second opening 42B are formed in the second insulation layer 42. In this step, the second insulation layer 42 is selectively removed by etching to form the first opening 42A and the second opening 42B extending through the second insulation layer 42. The first opening 42A exposes the surface of the source electrode 38. The second opening 42B exposes the surface of the drain electrode 40.

Subsequent to this step, a third metal layer is formed on the second insulation layer 42 so as to fill the first opening 42A and the second opening 42B. Then, the third metal layer is patterned, for example, by ion milling. In the present embodiment, the third metal layer may include a Ti layer having a thickness of approximately 10 nm, a Pt layer having a thickness of approximately 50 nm formed on the Ti layer, and an Au layer having a thickness of approximately 3 μm formed on the Pt layer. As a result, the nitride semiconductor device 10 including the source interconnect 14 and the drain interconnect 16 shown in FIG. 2 is obtained.

### Operation of Nitride Semiconductor Device

In the nitride semiconductor device 10, the gate electrode 20 is located between the source electrode 38 and the drain electrode 40, which are separated in the first direction D1, and extends in the second direction D2. The first direction D1 intersects the third direction D3, which coincides with the specific crystal direction in plan view, at an angle in a range of 90°±15°.

The source electrode 38, the gate electrode 20, and the drain electrode 40 are arranged in this order in the first direction D1. Thus, electrons travel in the first direction D1 between the source electrode 38 and the drain electrode 40. The third direction D3 is the inclination direction of the SiC substrate 22 and corresponds to a direction intersecting the steps 52 in plan view (refer to arrow B in FIG. 3). When the first direction D1 intersects the third direction D3 at an angle in a range of 90°±15°, electrons are less likely to travel in a direction intersecting the steps 52 in plan view. This limits increases in the scattering of electrons traveling in the first direction D1 between the source electrode 38 and the drain electrode 40, thereby enhancing the electron mobility when electrons travel between the source electrode 38 and the drain electrode 40.

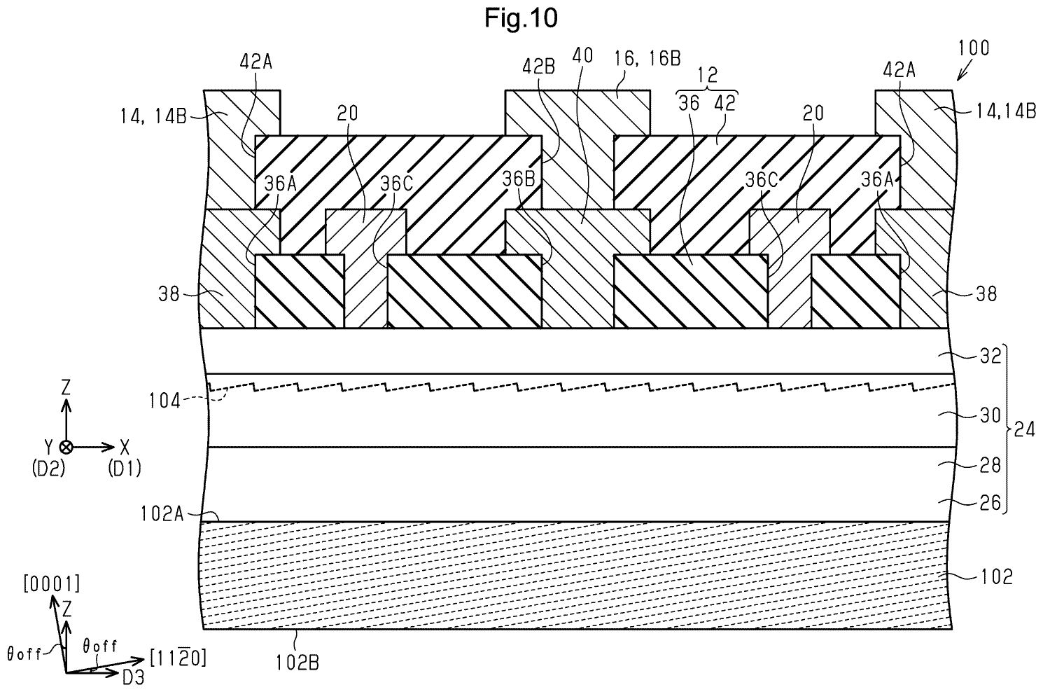

FIG. 10 is a schematic cross-sectional view of an exemplary nitride semiconductor device 100 in accordance with a comparative example. FIG. 10 shows a comparative example in which the first direction D1 is parallel to the third direction D3, which will be used to describe the improvement effect of the nitride semiconductor device 10 in the present embodiment on electron mobility. In FIG. 10, the same reference characters are given to those elements that are the same as the corresponding elements in the nitride semiconductor device 10 shown in FIG. 2. Such elements will not be described in detail.

As shown in FIG. 10, the nitride semiconductor device 100 includes a SiC substrate 102 including a main surface 102A and a back surface 102B. In the same manner as the SiC substrate 22 shown in FIG. 2, the SiC substrate 102 has a hexagonal crystal structure and has an off-angle θ_{off}. More specifically, the main surface 102A is inclined with respect to the c-plane by an off-angle θ_{off} in a range from 2° to 6°, inclusive, in the specific crystal direction. In this example, the specific crystal direction is the [11-20] direction. In the comparative example, the third direction D3, which coincides with the specific crystal direction in plan view, is parallel to the first direction D1 (X-axis direction). In the nitride semiconductor device 100, in the same manner as the nitride semiconductor device 10, the source electrode 38, the gate electrode 20, and the drain electrode 40 are arranged in this order in the first direction D1. Thus, in the comparative example, electrons travel in a direction intersecting the steps 52 in plan view (refer to arrow B in FIG. 3).

The nitride semiconductor layer 24 is an epitaxial layer located on the main surface 102A of the SiC substrate 102. Thus, the nitride semiconductor layer 24 may take on the crystal structure of the main surface 102A of the SiC substrate 102. As in the comparative example, when the first direction D1 (electron traveling direction) is parallel to the third direction D3 (inclination direction of the SiC substrate 102), the scattering of electrons traveling in the first direction D1 through the 2DEG 104, which is generated in the electron transit layer 30, may be relatively large. As a result, the electron mobility may be decreased in the nitride semiconductor device 100 of the comparative example.

In this regard, in the nitride semiconductor device 10 of the present embodiment, the first direction D1 (electron traveling direction) intersects the third direction D3 (inclination direction of SiC substrate 22) at an angle in a range of 90°±15°. Therefore, even when the nitride semiconductor layer 24 take on the crystal structure of the main surface 22A of the SiC substrate 22, increases in the scattering of electrons traveling in the first direction D1 through the 2DEG 34 are limited. As a result, the electron mobility is enhanced in the nitride semiconductor device 10 of the present embodiment.

The nitride semiconductor device 10 of the present embodiment has the following advantages.

(1) The SiC substrate 22 includes the main surface 22A inclined with respect to the c-plane at an off-angle θ_{off} in a range from 2° to 6°, inclusive, in the specific crystal direction. The gate electrode 20 is located between the source electrode 38 and the drain electrode 40, which are separated in the first direction D1, and extends in the second direction D2. The first direction D1 intersects the third direction D3, which coincides with the specific crystal direction in plan view, at an angle in a range of 90°±15°. This limits increases in the scattering of electrons traveling in the first direction D1 between the source electrode 38 and the drain electrode 40, thereby enhancing the electron mobility when electrons travel between the source electrode 38 and the drain electrode 40.

(2) The first direction D1 may intersect the third direction D3 at an angle in a range of 90°±10°. This further limits increases in the scattering of electrons traveling in the first direction D1 between the source electrode 38 and the drain electrode 40, thereby further enhancing the electron mobility when electrons travel between the source electrode 38 and the drain electrode 40.

(3) The electron transit layer 30 may be composed of GaN, and the electron supply layer 32 may be composed of AlₓGa₁₋ₓN, where 0.1<x<0.3. With this configuration, the 2DEG 34 having a desired sheet carrier density is generated in the electron transit layer 30.

(4) The nitride semiconductor layer 24 may include the semi-insulating layer 28. The electron transit layer 30 may be located on the semi-insulating layer 28. This reduces the leakage of current from the nitride semiconductor device 10.

(5) The nitride semiconductor layer 24 may include the buffer layer 26 located on the main surface 22A of the SiC substrate 22. This limits warping of the SiC substrate 22 and formation of cracks in the nitride semiconductor device 10.

### MODIFIED EXAMPLES

The above-described embodiment may be modified as follows.

The planar layout of the nitride semiconductor device 10 is not limited to the example shown in FIG. 1. In an example, the nitride semiconductor device 10 may include a back electrode located on the back surface 22B of the SiC substrate 22 and a contact plug extending through the nitride semiconductor layer 24. When the back electrode is connected to the source electrode 38 by the contact plug, the source interconnect 14 does not have to include the base 14A.

The polytype of the SiC substrate 22 is not limited to 4H. The SiC substrate 22 may be, for example, a 2H—SiC substrate or a 6H—SiC substrate.

One or more of the various examples described in this specification may be combined as long as there is no technical contradiction.

In this specification, “at least one of A and B” should be understood to mean “only A, only B, or both A and B”.

In the present disclosure, the term “on” may include the meaning of “above” in addition to the meaning of “on” unless otherwise clearly described in the context. Accordingly, the phrase of “first layer located on second layer” may mean that the first layer is located directly on the second layer contacting the second layer in one embodiment and that the first layer is located above the second layer without contacting the second layer in another embodiment. Thus, the word “on” will also allow for a structure in which another layer is located between the first layer and the second layer.

The directional terms used in the present disclosure such as “vertical,” “horizontal,” “above,” “below,” “top,” “bottom,” “frontward,” “backward,” “longitudinal,” “lateral,” “left,” “right,” “front,” and “back” will depend upon a particular orientation of the device being described and illustrated. In the present disclosure, a variety of alternative directions may be available for any given direction. Thus, directional terms should not be construed narrowly.

In an example, the Z-axis direction as referred to in the present disclosure does not necessarily have to be the vertical direction and does not necessarily have to fully conform to the vertical direction. Accordingly, in the structures disclosed above (e.g., structure shown in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

[Clause 1] A nitride semiconductor device, including:
a SiC substrate (22) having a hexagonal crystal structure and including a main surface (22A) being inclined with respect to a c-plane at an off-angle (θ_{off}) in a range from 2° to 6°, inclusive, in a specific crystal direction;
a nitride semiconductor layer (24) located on the main surface (22A) of the SiC substrate (22), the nitride semiconductor layer (24) including an electron transit layer (30) and an electron supply layer (32) located on the electron transit layer (30) and having a band gap larger than that of the electron transit layer (30); and
a gate electrode (20), a source electrode (38), and a drain electrode (40) located on the nitride semiconductor layer (24), in which
the main surface (22A) is parallel to a first direction (D1), a second direction (D2) orthogonal to the first direction (D1), and a third direction (D3) that coincides with the specific crystal direction in plan view,
the source electrode (38) and the drain electrode (40) are separated from each other in the first direction (D1), and the gate electrode (20) is located between the source electrode (38) and the drain electrode (40) and extends in the second direction (D2), and
the first direction (D1) intersects the third direction (D3) at an angle in a range of 90°±15°.

[Clause 2] The nitride semiconductor device according to clause 1, in which the off-angle (θ_{off}) is in a range from 3° to 5°, inclusive.

[Clause 3] The nitride semiconductor device according to clause 1, in which the off-angle (θ_{off}) is in a range from 3.5° to 4.5°, inclusive.

[Clause 4] The nitride semiconductor device according to any one of clauses 1 to 3, in which the specific crystal direction is a [11-20] direction.

[Clause 5] The nitride semiconductor device according to any one of clauses 1 to 4, in which the first direction (D1) intersects the third direction (D3) at an angle in a range of 90°±10°.

[Clause 6] The nitride semiconductor device according to any one of clauses 1 to 5, in which the SiC substrate (22) is a 4H—SiC substrate.

[Clause 7] The nitride semiconductor device according to any one of clauses 1 to 6, in which the SiC substrate (22) has a resistivity in a range from 1 Ω·m to 3 Ω·m, inclusive.

[Clause 8] The nitride semiconductor device according to any one of clauses 1 to 7, in which a two-dimensional electron gas (34) is generated in the electron transit layer (30).

[Clause 9] The nitride semiconductor device according to clause 8, in which the source electrode (38), the drain electrode (40) and the gate electrode (20) are located to allow an electron to transmit through the two-dimensional electron gas (34) in the first direction (D1).

[Clause 10] The nitride semiconductor device according to any one of clauses 1 to 9, in which
the gate electrode (20) is one of multiple gate electrodes (20) located on the nitride semiconductor layer (24), the source electrode (38) is one of multiple source electrodes (38) located on the nitride semiconductor layer (24), and the drain electrode (40) is one of multiple drain electrodes (40) located on the nitride semiconductor layer (24),
the multiple source electrodes (38) and the multiple drain electrodes (40) are alternately arranged in the first direction (D1), and
each of the multiple gate electrodes (20) is located between one of the multiple source electrodes (38) and one of the multiple drain electrodes (40).

[Clause 11] The nitride semiconductor device according to any one of clauses 1 to 10, in which
the electron transit layer (30) is composed of GaN, and
the electron supply layer (32) is composed of AlₓGa₁₋ₓN, where 0.1<x<0.3.

[Clause 12] The nitride semiconductor device according to any one of clauses 1 to 11, in which the electron transit layer (30) is an n-type GaN layer.

[Clause 13] The nitride semiconductor device according to any one of clauses 1 to 12, in which
the nitride semiconductor layer (24) further includes a semi-insulating layer (28), and
the electron transit layer (30) is located on the semi-insulating layer (28).

[Clause 14] The nitride semiconductor device according to clause 13, in which
the semi-insulating layer (28) is a GaN layer doped with an impurity, and
the impurity is carbon or iron.

[Clause 15] The nitride semiconductor device according to any one of clauses 1 to 14, in which the nitride semiconductor layer (24) is an epitaxial layer located on the main surface (22A) of the SiC substrate (22).

[Clause 16] The nitride semiconductor device according to any one of clauses 1 to 15, in which the nitride semiconductor layer (24) further includes a buffer layer (26) located on the main surface (22A) of the SiC substrate (22).

[Clause 17] The nitride semiconductor device according to clause 16, in which the buffer layer (26) includes an AlN layer located on the main surface (22A) of the SiC substrate (22) and an AlGaN layer located on the AlN layer.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a SiC substrate having a hexagonal crystal structure and including a main surface being inclined with respect to a c-plane at an off-angle in a range from 2° to 6°, inclusive, in a specific crystal direction;
a nitride semiconductor layer located on the main surface of the SiC substrate, the nitride semiconductor layer including an electron transit layer and an electron supply layer located on the electron transit layer and having a band gap larger than that of the electron transit layer; and
a gate electrode, a source electrode, and a drain electrode located on the nitride semiconductor layer, wherein
the main surface is parallel to a first direction, a second direction orthogonal to the first direction, and a third direction that coincides with the specific crystal direction in plan view,
the source electrode and the drain electrode are separated from each other in the first direction, and the gate electrode is located between the source electrode and the drain electrode and extends in the second direction, and
the first direction intersects the third direction at an angle in a range of 90°±15°.

2. The nitride semiconductor device according to claim 1, wherein the off-angle is in a range from 3° to 5°, inclusive.

3. The nitride semiconductor device according to claim 1, wherein the off-angle is in a range from 3.5° to 4.5°, inclusive.

4. The nitride semiconductor device according to claim 1, wherein the specific crystal direction is a [11-20] direction.

5. The nitride semiconductor device according to claim 1, wherein the first direction intersects the third direction at an angle in a range of 90°±10°.

6. The nitride semiconductor device according to claim 1, wherein the SiC substrate is a 4H—SiC substrate.

7. The nitride semiconductor device according to claim 1, wherein the SiC substrate has a resistivity in a range from 1 Ω·m to 3 Ω·m, inclusive.

8. The nitride semiconductor device according to claim 1, wherein a two-dimensional electron gas is generated in the electron transit layer.

9. The nitride semiconductor device according to claim 8, wherein the source electrode, the drain electrode and the gate electrode are located to allow an electron to transmit through the two-dimensional electron gas in the first direction.

10. The nitride semiconductor device according to claim 1, wherein
the gate electrode is one of multiple gate electrodes located on the nitride semiconductor layer, the source electrode is one of multiple source electrodes located on the nitride semiconductor layer, and the drain electrode is one of multiple drain electrodes located on the nitride semiconductor layer,
the multiple source electrodes and the multiple drain electrodes are alternately arranged in the first direction, and
each of the multiple gate electrodes is located between one of the multiple source electrodes and one of the multiple drain electrodes.

11. The nitride semiconductor device according to claim 1, wherein
the electron transit layer is composed of GaN, and
the electron supply layer is composed of AlₓGa₁₋ₓN, where 0.1<x<0.3.

12. The nitride semiconductor device according to claim 1, wherein the electron transit layer is an n-type GaN layer.

13. The nitride semiconductor device according to claim 1, wherein
the nitride semiconductor layer further includes a semi-insulating layer, and
the electron transit layer is located on the semi-insulating layer.

14. The nitride semiconductor device according to claim 13, wherein
the semi-insulating layer is a GaN layer doped with an impurity, and
the impurity is carbon or iron.

15. The nitride semiconductor device according to claim 1, wherein the nitride semiconductor layer is an epitaxial layer located on the main surface of the SiC substrate.
